(19) United States
(12) Patent Application Publication
(10) Pub. No.: US 2010/0233354 A1
(43) Pub. Date: Sep. 16, 2010

(54) Device for Creating a Printing Plate and Development Process

(76) Inventors: Christian Barral, Uffholtz (FR); David Brazier, High Wycombe (GB)

Correspondence Address: ARTHUR G. SCHAIER;CARMODY & TORRANCE LLP, 50 LEAVENWORTH STREET, P.O. BOX 1110, WATERBURY, CT, 06721, US

(21) Appl. No.: 12/301,804

(22) PCT Filed: May 24, 2007
(86) PCT No.: PCT/FR2007/051325

§ 371 Date: Nov. 21, 2008

(30) Foreign Application Priority Data
May 29, 2006 (FR) 06 51933

(51) Int. Cl. C23C 14/54

(52) U.S. Cl. 427/9; 118/708

(57) ABSTRACT

The invention concerns a device forcreating a printing plate including a support (1) designed to be exposed to liquid photopolymer then a film designed to constitute the base of the printing plate, a means of application (3) of the liquid photopolymer on the support (1) in a layer (2) of predetermined thickness and a means of verification (5) of the actual thickness of the layer (2) applied. The means of verification includes a detector (5), mounted on the downstream side of the means of application (3), such that it is situated over a section of the photopolymer layer (2) that has just been applied, the detector (5) generating an electric signal, on the basis of which the flow of photopolymer is adjusted, when the actual thickness of the layer (2) applied differs from the predetermined value. The invention also concerns a procedure of making a printing plate, preferably implemented via said device.

The present invention relates to a device for the production of a printing plate, as well as to a process for production thereof.

Ordinarily, a printing plate is obtained by laying down a support, such as a translucent plate or a plate provided with a negative of a page to be printed, on a work top or table and by then applying successively on the support a liquid photopolymer and then a film intended for constituting the base of the printing plate. Then, the thickness of the printing plate is measured, and if this thickness differs from a predetermined thickness or reference thickness, the means with which the photopolymer is applied are adjusted so as to obtain the desired thickness of the printing plate.

In order to apply the photopolymer, devices having a reservoir from which the photopolymer comes out by gravity are preferably used. For this purpose, the reservoir is provided with an outlet in the form of a slot oriented downward, and the liquid photopolymer is then applied, going from the reservoir onto the support, while the reservoir moves by above the support according to a direction of movement. In order to adjust the thickness of the polymer layer to be obtained, one determines, according to the viscosity of the photopolymer, a speed at which the reservoir has to move by above the support. The higher the speed of the reservoir is, the thinner the thickness of the photopolymer layer deposited will be. As a consequence, in order to adjust the thickness of the photopolymer layer to be obtained, one varies the speed at which the reservoir moves by.

And in order to deposit the film intended for constituting the base of the printing plate to be produced, it is possible to use, for example, a device that has a pay-out device in which a spool of film is mounted.

The device for production of a printing plate with a design of this type has the advantage of a simple structure and the absence of complicated adjustment mechanisms.

However, a design of this type nevertheless has drawbacks. First of all, although the photopolymers are called “liquid,” they are viscous, and their viscosity, at a given temperature, can vary from one delivery lot to another. Furthermore, the viscosity varies according to the ambient temperature prevailing around the device for production of the printing plates.

The viscous nature of the photopolymers, as opposed to the behavior of a liquid product such as water, makes the photopolymers come out of the reservoir by gravity flow with an inherent speed that is not only a function of the degree of viscosity of the polymer but also of the configuration of the outlet slot of the reservoir.

So in order to vary the flow rate of the photopolymer to be deposited, one generally chooses to vary the speed of movement of the reservoir above the support. However, when the speed of movement exceeds a limit, which generally differs from one photopolymer to another, there may be an irregular flow rate of the photopolymer or even breaking of the flow of photopolymer.

Another drawback of the system described above lies in the fact that the entire thickness of the printing plate is measured. Thus, in the case in which there is a difference between the reference thickness and the thickness actually measured, it is not possible to distinguish between an error in the thickness of the photopolymer layer and an error due to a problem of positioning or of the thickness of the film. Consequently, it is impossible to provide precisely targeted corrections in order to obtain a printing plate according to the predetermined dimensions.

The aim of the invention is to remedy the drawbacks described above.

The aim of the invention is attained with a device for the production of a printing plate, which has a support intended for receiving a liquid photopolymer and then a film intended for constituting the base of the printing plate, a means for application of the liquid photopolymer on the support in the form of a layer having a surface and a predetermined thickness and a means for verification of the thickness of the applied layer.

According to the invention, the verification means includes a detector mounted on the downstream side of the application means in such a way as to be arranged above a part of the photopolymer layer that has just been applied, a comparator intended for comparing the actual thickness of the part of the polymer layer just applied with the predetermined thickness and a generator of electrical signals intended for generating a correction signal in the case in which there is a difference between the actual thickness and the predetermined thickness, the generator being connected to a device for adjustment of the flow rate of photopolymer from the application means.

The device of the invention provides the advantage of being able to verify the thickness of just the photopolymer layer and of being able to do this continually and above all in a part of the photopolymer layer that has just been applied. Thanks to the short distance between the place where the liquid photopolymer falls on the support and the part of the photopolymer layer where the thickness is verified, the reaction in case of drift from the predetermined thickness is practically immediate.

Furthermore, the arrangements of the invention make it possible to place the means for application of the film rather close to the means for application of the photopolymer. The arrangements of the invention therefore do not lead to an appreciable enlargement of the device for production of a printing plate.

The arrangements of the invention furthermore, according to a preferred embodiment of the invention, make it possible not to measure the actual thickness of the applied photopolymer layer, but rather to verify whether the surface of the deposited photopolymer layer remains at a constant level or not. In effect, in case of production of a photopolymer layer with an ideally constant thickness, the constant level of the surface of the photopolymer layer is then representative of the constancy of the thickness of the layer that is produced.

This arrangement of the invention is particularly advantageous because of the transparency of the liquid photopolymers. Furthermore, the support is often black. Consequently, the thickness of the applied layer is difficult to measure with optical reflection means. On the other hand, it is easier to monitor the level of the surface of the applied layer with a reflection detector, preferably with a detector of the type operating by defined reflection.

This type of detector uses the reflection of a beam of light on the surface of the resin in the case of a non-normal incidence. One speaks of specular reflection on a very smooth surface (as is the case of a liquid) with an angle of incidence that is equal and opposite with respect to the normal to the angle of reflection.

The principle of verification of the level of the surface of the applied layer furthermore offers the advantage of a simple device functioning over a wide range of polymer layer thicknesses. In effect, the device of the invention in the embodiment explained only uses the level of the surface of the layer; the thickness of the photopolymer layer has become unimportant.

At the same time, this simplifies the device for production of the printing plates. In effect, such a device can be equipped with a table or work top or any other means configured for maintaining or bearing the support on which the photopolymer has to be applied and for arranging this table at a variable level with respect to the photopolymer application means. In other words, according to a first execution variant, the table is mounted so as to be mobile in such a way that it can be moved farther from or closer to the photopolymer application means and so that in this way a predetermined thickness or reference thickness is adjusted. According to a second variant, the table is mounted in a fixed position, and it is the photopolymer application means and the film pay-out device that are mobile so that they can be moved closer to and farther from the table.

According to another characteristic of the present invention, the application means includes apportioning means. This arrangement of the invention makes it possible to make the photopolymer application means move by with respect to the support with a constant speed of movement or of application. More particularly, this arrangement of the invention makes it possible to use a constant speed motor, which simplifies the device of the invention thanks to the absence of a variable speed drive.

According to yet another characteristic of the invention, the application means includes a reservoir for the photopolymer, and some apportioning means at the outlet of the reservoir. The apportioning means can be arranged immediately after the outlet of the reservoir. However, it is preferable for the outlet of the reservoir, which is generally present in the form of a slot, to be formed at least partially by the apportioning means.

According to a particular embodiment of the invention, the reservoir is configured so that the photopolymer can come out of it through a slot with a variable opening, this slot being formed between a scraper and a cylindrical body with a non-circular cross section. The scraper and the cylindrical body being mounted on the reservoir are an integral part of it. The variation of the opening of the slot is obtained by rotation of the cylindrical body around its longitudinal axis in accordance with an electrical correction signal generated by the detector verifying the constancy of the level of the surface of the deposited polymer layer.

According to an execution variant represented in the drawings, the cylindrical body is provided with a flat part extending according to a plane parallel to its longitudinal axis. This flat part gives the cross section of the cylindrical body the non-circular form. With the non-circular side of the cross section being oriented towards the scraper, and the outlet slot of the reservoir therefore being delimited between the non-circular side of the cylindrical body and the scraper, the opening of the slot can be varied by rotation of the cylindrical body around its longitudinal axis.

According to another aspect of the invention, the scraper is arranged above the support intended for receiving a photopolymer layer, at a height that is greater than the predetermined thickness of the photopolymer layer to be applied.

In order to guarantee a homogeneous flow rate of photopolymer with a chosen speed of movement of the application means, it is recommended that the height at which the scraper is arranged with respect to the support to be approximately 2 mm larger than the thickness of the photopolymer layer to be produced.

The aim of the invention is also attained with a process for production of a printing plate by means of a device that has a support intended for receiving a liquid photopolymer and then a film intended for constituting the base of the printing plate, a means for application of the liquid photopolymer on the support in the form of a layer having a surface and a predetermined thickness and a means for verification of the thickness of the applied layer.

According to the invention, the process includes at least the following steps:
laying down a support intended for receiving a layer of liquid photopolymer,
applying the liquid photopolymer on the support in the form of a layer having a surface and a predetermined thickness,
verifying the thickness of the part of the polymer layer that has just been applied,
generating a correction signal if the actual thickness differs from the predetermined thickness, and
readjusting an apportioning device of the application means in accordance with the correction signal.

This process is advantageously implemented using the device described above.

Other characteristics and advantages of the present invention will emerge in the description hereafter of an embodiment of the device of the invention. The description is given in reference to the drawings, in which:

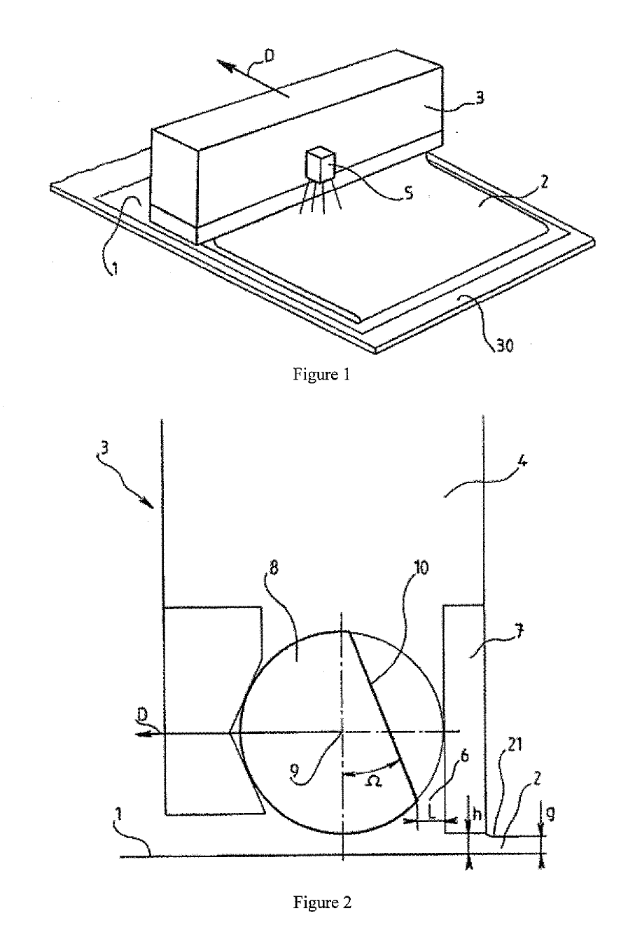

FIG. 1 very schematically represents a device of the invention, and

FIG. 2 represents the arrangement of the different elements of the application means of the device of the invention in the form of a side view.

FIG. 1 represents a device for the production of a printing plate according to the invention. This device has support 1 intended for receiving a liquid photopolymer and then a film intended for constituting the base of the printing plate, as well as means 3 for application of the liquid photopolymer on support 1 in the form of layer 2 and means 5 for verification of the thickness of applied layer 2. During the deposition of layer 2, application means 3 moves with respect to support 1 according to direction D. Support 1 rests on table 30.

Verification means 5 includes a detector mounted on the downstream side of application means 3. Detector 5 is thus arranged above a part of photopolymer layer 2 that has just been applied. Detector 5 is connected to a comparator (not represented) intended for comparing the actual thickness of the part of polymer layer 2 just applied with the predetermined thickness. The comparator has or is connected to a generator of electrical signals intended for generating a correction signal in the case in which there is a difference between the actual thickness and the predetermined thickness of the photopolymer layer. The electrical signal generator is connected to a device for adjustment of the flow rate of the photopolymer from application means 3.

In a device or installation for production of printing plates, table 30 and application device 3 are advantageously mounted in such a way that one can be shifted in terms of elevation with respect to the other. Generally, it will be easier to mount table 30 so as to be mobile with respect to application means 3 that is mounted fixed.

FIG. 2 represents the different elements of application means 3 and the position with respect to support 1.

Application means 3 includes reservoir 4 for the photopolymer, and apportioning means 7, 8 at the outlet of reservoir 4. Apportioning means 7, 8 include scraper 7 and cylindrical body 8 with longitudinal axis 9 and a non-circular cross section. The non-circular form of the cross section of body 8 is obtained by flat part 10 that extends according to a plane parallel to longitudinal axis 9 of cylindrical body 8. Flat part 10 is oriented towards scraper 7 in such a way as to define slot 6 with variable opening L between scraper 7 and cylindrical body 8. The variation of opening L of slot 6 is obtained by rotation of cylindrical body 8 around its longitudinal axis 9 in accordance with an electrical correction signal generated by detector 5.

The orientation of flat part 10 with respect to a vertical plane is indicated in the figure by angle of opening Ω. The smaller the angle of opening Ω is, the larger opening L of slot 6 is.

FIG. 2 furthermore also depicts thickness g of photopolymer layer 2 and height h at which scraper 7 is arranged. Without a numerical indication, FIG. 2 clearly shows that height h is greater than thickness g of photopolymer layer 2.

It goes without saying that the embodiment using cylindrical body 8 with a flat part is one embodiment among others. It will be possible, without leaving the scope of the invention, to use a valve system or a mobile slot system or a functional equivalent.

The expert in the field will easily see that thickness g of deposited photopolymer layer 2 can be varied while keeping a constant speed of application.

1. A device for the production of a printing plate, which has (i) a support for receiving both a liquid photopolymer and a film for constituting the base of the printing plate, (ii) means for application of the liquid photopolymer on the support in the form of layer having surface and predetermined thickness and (iii) means for verification of the thickness of the layer, the verification means including a detector mounted on the downstream side of application means in such a way as to be arranged above a part of the layer, a comparator intended for comparing the actual thickness of the part of the layer with the predetermined thickness and a generator of electrical signals intended for generating a correction signal in the case in which there is a difference between the actual thickness and the predetermined thickness, the generator being connected to a device for adjustment of the flow rate of the photopolymer from application means, this level being representative of the actual thickness of photopolymer layer characterized by the fact that detector (5) is of the type operating by defined reflection.

2. A device according to claim 1, characterized by the fact that application means (3) includes apportioning means.

3. A device according to claim 1, characterized in that the application means includes a reservoir for the photopolymer, and apportioning means at the outlet of the reservoir.

4. A device according to claim 3, characterized in that the reservoir is configured so that the photopolymer can come out of it through a slot with variable width (L) formed between a scraper and a cylindrical body with a non-circular cross section, which are mounted on the reservoir, the non-circular side being oriented towards the scraper, and the variation of the width of the slot being obtained by rotation of cylindrical body around its longitudinal axis in accordance with an electrical correction signal generated by detector.

5. A device according to claim 4, characterized in that cylindrical body is provided with flat part extending according to a plane parallel to a longitudinal axis of the cylindrical body, this flat part giving the cross section of cylindrical body the non-circular form.

6. A device according to claim 4, characterized in that the scraper is arranged above the support at a height that is greater than predetermined thickness of the photopolymer layer to be applied.

7. A device according to claim 6, characterized in that the height at which the scraper is arranged is approximately 2 mm larger than predetermined thickness of the photopolymer layer.

8. A device according to claim 1, characterized in that in order to maintain support, the device has a table mounted at a variable level with respect to the means for application of the liquid photopolymer.

9. A device according to claim 1, characterized in that the device comprises in that a constant speed motor for making the application means move by over the support.

10. A process for production of a printing plate by means of a device that comprises (i) a support for receiving both a liquid photopolymer and a film for constituting the base of the printing plate, (ii) a means for application of the liquid photopolymer on the support in the form of a layer having a surface and a predetermined thickness and (iii) means for verification of thickness of the layer,
characterized in that the process includes at least the following steps:
laying down the support for receiving the layer of liquid photopolymer,
applying the liquid photopolymer on the support in the form of a layer having a surface and predetermined thickness,
verifying the thickness of a part of the layer,
generating a correction signal if the actual thickness differs from predetermined thickness, and
readjusting an apportioning device of the application means in accordance with the correction signal.

11. A process according to claim 10, characterized in that the application means moves above the support with a constant speed of application.
